(19) United States
(12) Patent Application Publication
(10) Pub. No.: US 2026/0291497 A1
(43) Pub. Date: Sep. 24, 2026

(54) APPARATUS AND TECHNIQUES FOR CLOCK SIGNAL GENERATION

(71) Applicant: QUALCOMM Incorporated, San Diego, CA (US)

(72) Inventor: Behnam SEDIGHI, La Jolla, CA (US)

(21) Appl. No.: 19/083,137

(22) Filed: Mar. 18, 2025

(51) Int. Cl. H03K 17/687; G11C 27/02; H02M 3/07; H03M 1/12

(52) U.S. Cl. CPC H03K 17/6871; G11C 27/02; H02M 3/07; H03M 1/1245

(57) ABSTRACT

Certain aspects of the present disclosure are directed towards a clock generation circuit. The clock generation circuit generally includes: a charge pump including a capacitive element; a first transistor coupled between a first terminal of the capacitive element and an auxiliary clock (CKₐᵤₓ) node; a second transistor coupled between the first terminal of the capacitive element and a boosted clock (CK_{bst}) node; an input transistor with a gate coupled to the CKₐᵤₓ node, a drain coupled to an input voltage node, and a source coupled to a second terminal of the capacitive element; a first gate drive circuit coupled to a gate of the first transistor; and a second gate drive circuit coupled to a gate of the second transistor, the second gate drive circuit being separate from the first gate drive circuit.

### TECHNICAL FIELD

Certain aspects of the present disclosure generally relate to electronic circuits and, more particularly, to a clock generation circuit.

### BACKGROUND

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system). Wireless devices may include transmitters for processing signals for transmission and a receiver for processing received signals. The receiver may include an analog-to-digital converter (ADC) for converting a received signal from an analog domain to a digital domain. In some cases, the ADC may include a sample-and-hold circuit to sample an input voltage for analog-to-digital conversion.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards a clock generation circuit. The clock generation circuit generally includes: a charge pump including a capacitive element; a first transistor coupled between a first terminal of the capacitive element and an auxiliary clock (CKₐᵤₓ) node; a second transistor coupled between the first terminal of the capacitive element and a boosted clock (CK_{bst}) node; an input transistor with a gate coupled to the CKₐᵤₓ node, a drain coupled to an input voltage node, and a source coupled to a second terminal of the capacitive element; a first gate drive circuit coupled to a gate of the first transistor; and a second gate drive circuit coupled to a gate of the second transistor, the second gate drive circuit being separate from the first gate drive circuit.

Certain aspects of the present disclosure are directed towards a method for clock generation. The method generally includes: providing, via an input transistor, an input voltage to a charge pump; generating a boosted voltage via the charge pump based on the input voltage; driving, via a first gate drive circuit, a gate of a first transistor to provide the boosted voltage to a CKₐᵤₓ node and generate a CKₐᵤₓ signal, the CKₐᵤₓ signal being provided to a gate of the input transistor; and driving, via a second gate drive circuit, a gate of a second transistor to provide the boosted voltage to a CK_{bst} node and generate a CK_{bst} signal, the second gate drive circuit being separate from the first gate drive circuit.

Certain aspects of the present disclosure are directed towards a sample-and-hold circuit. The circuit generally includes: a sampling transistor coupled to an input voltage node and a clock generation circuit comprising: a charge pump including a capacitive element; a first transistor coupled between a first terminal of the capacitive element and a CKₐᵤₓ node; a second transistor coupled between the first terminal of the capacitive element and a CK_{bst} node, CK_{bst} node being coupled to a gate of the sampling transistor; an input transistor with a gate coupled to the CKₐᵤₓ node, a drain coupled to the input voltage node, and a source coupled to a second terminal of the capacitive element; a first gate drive circuit coupled to a gate of the first transistor; and a second gate drive circuit coupled to a gate of the second transistor, the second gate drive circuit being separate from the first gate drive circuit.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a block diagram of an example electronic device, in which aspects of the present disclosure may be practiced.

FIG. 2 illustrates an example sample-and-hold circuit implemented with a clock bootstrap circuit.

FIG. 3 illustrates an example clock bootstrapping circuit, in accordance with certain aspects of the present disclosure.

FIG. 4 is a flow diagram illustrating example operations for clock generation, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards a clock generation circuit, also referred to as a clock bootstrap circuit. The clock generation circuit may generate a boosted clock (CK_{bst}) signal at a CK_{bst} node based on a clock (CK) signal and an input voltage for a load circuit, such as a sample-and-hold circuit. The clock generation circuit may be implemented with a charge pump to generate a boosted voltage based on the CK signal and the input voltage. The boosted voltage may be selectively provided to the CK_{bst} node and an auxiliary clock (CKₐᵤₓ) node via respective transistors. The CKₐᵤₓ signal at the CKₐᵤₓ node may be used to control an input transistor used to provide the input voltage to the charge pump. When the CK signal transitions from logic high to logic low, the input transistor may be turned off quickly to avoid disturbances at the input voltage node causing intermodulation products, as described in more detail herein. In some aspects, separate gate drive circuits may be used to drive gates of the transistors used to provide the boosted voltage to the CK_{bst} node and the CKₐᵤₓ node such that the input transistor can be more quickly turned off, reducing the intermodulation products.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatuses, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCS), personal digital assistants (PDAs), and the like.

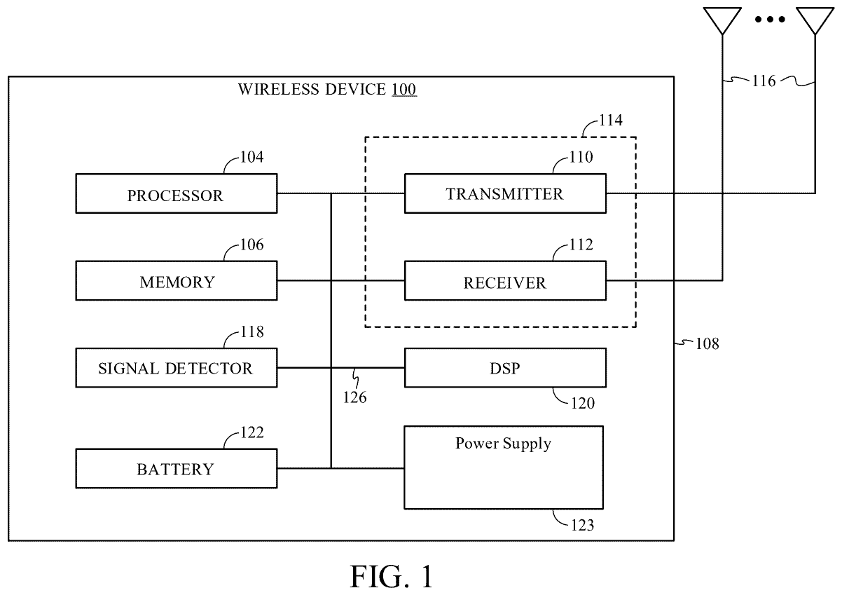

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an Internet of things (IoT) device, a wearable device, a virtual reality (VR) or augmented reality (AR) device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may include an analog-to-digital converter (ADC) implemented with a sample-and-hold circuit. Certain aspects of the present disclosure are directed towards a clock bootstrap circuit used to generate a boosted clock signal to drive a sample transistor of the sample-and-hold circuit, as described in more detail herein.

The device 100 may further include a battery 122, which may be used to power the various components of the device 100 (e.g., when the device is disconnected from an external power source). The device 100 may also include a power supply system 123 for managing the power from the battery (or from one or more power ports for receiving external power) to the various components of the device 100.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Clock Generation Circuit

Certain aspects are directed towards a clock bootstrap circuit (e.g., also referred to herein as a “clock generation circuit”) that may receive a clock (CK) signal and generate a boosted clock (CK_{bst}) signal having a higher logic high voltage than the CK signal. The clock bootstrap circuit may be used for various applications, such as high-speed or high-linearity sample-and-hold circuits. In some cases, sample-and-hold circuits may be used to implement analog-to-digital converters (ADCs). For example, the sample-and-hold circuit may be used to sample an analog input voltage (Vin) to be converted from the analog domain to the digital domain via the ADC.

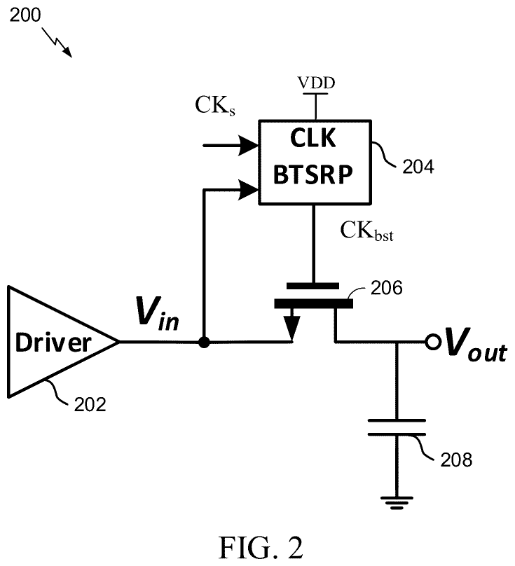

FIG. 2 illustrates an example sample-and-hold circuit 200 implemented with a clock bootstrap circuit 204 (e.g., labeled “CLK BTSTRP”). As shown, the clock bootstrap circuit 204 may receive a sample clock (CKₛ) signal and Vin from a driver 202. The clock bootstrap circuit 204 generates a boosted clock (CK_{bst}) signal that is used to drive a gate of a sample transistor 206 to turn on the transistor 206 and sample Vin on a capacitive element 208, generating an output voltage Vout. The CK_{bst} signal may have a logic high voltage equal to Vin plus αVDD where VDD is a supply voltage (e.g., at a voltage rail labeled “VDD”) provided to the clock bootstrap circuit 204 and α is a value slightly less than 1 (e.g., accounting for losses within the clock bootstrap circuit). The logic low voltage of the CK_{bst} signal may be zero volts.

The linearity of the sample-and-hold circuit impacts the performance of the ADC. In high-performance circuits, clock bootstrapping is used to keep the gate-to-source voltage (Vgs) of the sampling transistor (e.g., transistor 206) signal-independent (e.g., since CK_{bst} signal is a function of Vin and thus changes in Vin impact both the source voltage of the transistor 206 and the CK_{bst} signal provided to the gate of the transistor 206). However, the clock bootstrap circuit may sink signal-dependent current from the source (e.g., sink current from the Vin node), which may cause non-linearity resulting in intermodulation products. Certain aspects of the present disclosure are directed towards a clock bootstrap circuit with increased linearity as compared to conventional implementations.

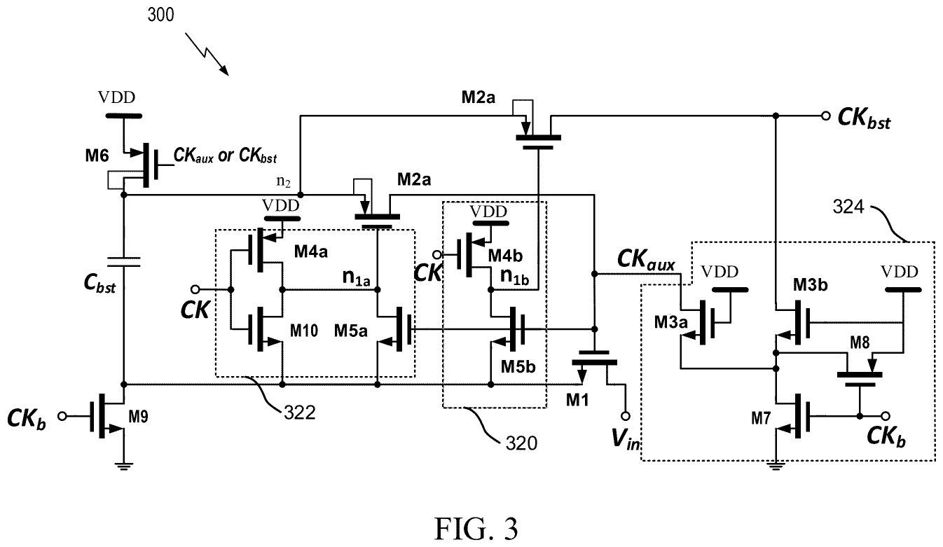

FIG. 3 illustrates an example clock bootstrap circuit 300 (e.g., corresponding to the clock bootstrap circuit 204 of FIG. 2), in accordance with certain aspects of the present disclosure. The circuit 300 may be implemented using a charge pump with a boost capacitive element C_{bst}, an n-type metal-oxide-semiconductor (NMOS) transistor M9, and a p-type metal-oxide-semiconductor (PMOS) transistor M6. The source of transistor M6 may be coupled to VDD and the source of transistor M9 may be coupled to a reference potential node. The drains of transistors M9, M6 may be coupled to first and second terminals of C_{bst}, respectively. The charge pump may generate a boosted voltage at node n₂ (e.g., at the second terminal of C_{bst}).

The circuit 300 may receive a clock (CK) signal and a complementary clock (CK_{b}) signal. The CK_{b} signal is used to drive the gate of transistor M9. The circuit 300 may generate an auxiliary CK (CKₐᵤₓ) signal that may be a boosted version of the CK signal (e.g., similar to the CK_{bst} signal). When the CK_{b} signal is logic high and the CKₐᵤₓ signal is logic low, transistor M9 is turned on, coupling the first terminal of C_{bst} to the reference potential node, and transistor M6 is turned on, coupling the second terminal of C_{bst} to VDD, charging C_{bst} to VDD. As shown, the CKₐᵤₓ signal is used to drive the gate of transistor M1 (e.g., also referred to herein as an “input transistor”) having a drain coupled to the Vin node and a source coupled to the first terminal of C_{bst}. When CK_{b} signal is logic low and the CKₐᵤₓ signal is logic high, transistors M6, M9 are turned off and transistor M1 is turned on, providing Vin to the first terminal of C_{bst}. Thus, the voltage at node n₂ may be equal to Vin plus VDD stored on C_{bst}. Thus, the signal at node n₂ may transition between VDD and Vin plus VDD. In some cases, two separate paths including respective transistors M2a and M2b may be used to generate the CKₐᵤₓ signal and the CK_{bst} signal, respectively. The transistor M2a may be a smaller transistor with a lower parasitic capacitance than transistor M2b since transistor M2b provides power to a load (e.g., transistor 206 of FIG. 2).

The circuit 300 may include a gate drive circuit 322 for transistor M2a. The gate drive circuit 322 may include a PMOS transistor M4a and an NMOS transistor M10. The source of transistor M4a may be coupled to VDD and the source of transistor M10 may be coupled to the source of transistor M1 and the first terminal of Cbst. The gates of transistors M4a and M10 may be coupled to the CK node to receive the CK signal. The drains of transistors M4a and M10 may be coupled to node n₁ₐ at the gate of transistor M2a.

When the CK signal is logic low, the transistor M4a is turned on, providing VDD to node n₁ₐ at the gate of transistor M2a. The voltage at the source of transistor M2a may be at VDD (e.g., due to transistor M6 being turned on). Thus, the source-to-gate voltage of transistor M2a may be equal to zero volts, turning off transistor M2a.

When the CK signal is logic high, the transistors M1 and M10 are turned on, pulling down the voltage at the gate of transistor M2a to Vin. The voltage at the source of transistor M2a may be Vin plus VDD, resulting in the source-to-gate voltage of transistor M2a being equal to VDD, turning on transistor M2a and setting CKₐᵤₓ equal to Vin plus VDD. As shown, the circuit 300 may also include a transistor M5a with a drain coupled to the gate of transistor M2a and a source coupled to the source of transistor M1. The gate of transistor M5a is coupled to the CKₐᵤₓ node. Thus, the transistor M5a may also be turned on, assisting in pulling down the voltage at node n₁ₐ from VDD to Vin.

In certain aspects of the present disclosure, separate gate drive circuits 322, 320 may be used to drive the gates of transistors M2a and M2b, respectively. For example, the gate drive circuit 320 may include a PMOS transistor M4b with a source coupled to VDD, a gate coupled to the CK node, and a drain coupled to node n_{1b} at the gate of transistor M2b. The circuit 320 also includes a transistor M5b with a drain coupled to node n_{1b}, a source coupled to the source of transistor M1, and a gate coupled to the CKₐᵤₓ node.

When the CK signal is logic low, the transistor M4b is turned on, providing VDD to node n_{1b} at the gate of transistor M2b. The voltage at the source of transistor M2b may be at VDD (e.g., due to transistor M6 being turned on). Thus, the source-to-gate voltage of transistor M2b may be equal to zero volts, turning off transistor M2b.

When the CK signal is logic high, the transistors M1 and M5b are turned on, pulling down the voltage at node n_{1b} (e.g., at the gate of transistor M2a) to Vin. The voltage at the source of transistor M2b may be Vin plus VDD, resulting in the source-to-gate voltage of transistor M2b being equal to VDD, turning on transistor M2b and setting CK_{bst} equal to Vin plus VDD.

As described, the transistor M2b may be a larger transistor with higher parasitic capacitance as compared to transistor M2a because transistor M2b is used to provide power load circuitry (e.g., transistor 206 of FIG. 2) that may consume higher currents as compared to CK_{bst} that is supported via transistor M2a. Thus, charging and discharging the capacitance of transistor M2b may take more time than transistor M2a. If the same gate drive circuit was used to drive the gates of both transistors M2a and M2b, the higher parasitic capacitance of transistor M2b may also delay how quickly transistor M2a is turned on and off. Using a separate gate drive circuit 320 to drive the gate of transistor M2b, the node n₁ₐ can be used to turn on and off transistor M2a more quickly, resulting in the CKₐᵤₓ signal having faster rise and fall times. When the CKₐᵤₓ signal transitions from logic high to logic low, if transistor M1 is not turned off quickly, current may sink from the Vin node to the reference potential node through transistor M9, causing non-linearity and disturbances that may cause intermodulation products associated with the sample-and-hold circuit. With the CKₐᵤₓ signal having a quicker fall time, transistor M1 may be turned off more quickly, increasing linearity and reducing the intermodulation products.

The circuit 300 may also include a pull-down circuit 324 to pull the voltage at the CK_{bst} and CKₐᵤₓ nodes to zero volts when the CK signal is logic low. For example, the circuit 300 may include a transistor M3a with a drain coupled to the CKₐᵤₓ node, a gate coupled to VDD, and a source coupled to a drain of transistor M7. A source of transistor M7 may be coupled to the reference potential node and a gate of transistor M7 may be coupled to the CK_{b} node. A source of transistor M8 may be coupled to VDD and a gate of transistor M3b, a gate of transistor M8 may be coupled to the CK_{b} node, and a drain of transistor M8 may be coupled to the drain of transistor M7. A drain of transistor M3b may be coupled to the CK_{bst} node, a source of transistor M3b may be coupled to the drain of transistor M7, and a gate of transistor M3b may be coupled to VDD.

When CK_{b} signal is logic high (e.g., CK signal is logic low), the transistor M7 may be turned on, the transistor M8 may be turned off, the transistor M3b may be turned on, and the transistor M3a may be turned on. Thus, the voltage at the CK_{bst} and CKₐᵤₓ nodes may be pulled down to zero volts.

When the CK_{b} signal is low (e.g., CK signal is logic high), the transistor M7 may be turned off, the transistor M8 may be turned on, the transistor M3b may be turned off, and the transistor M3a may be turned off. The transistor M8 being turned on effectively shorts across the gate and source of each of transistors M3a and M3b to turn off transistors M3a and M3b. The transistor M3a is included between the CKₐᵤₓ node and the drain of transistor M7 to increase the overall breakdown voltage between the CKₐᵤₓ node and the reference potential node. In other words, without the transistor M3a, the voltage at the CKₐᵤₓ node (Vin plus VDD) may be applied across the drain and source of transistor M7 and the breakdown voltage of transistor M7 may not be able to withstand the voltage. Similarly, the transistor M3b increases the overall breakdown voltage between the CK_{bst} node and the reference potential node.

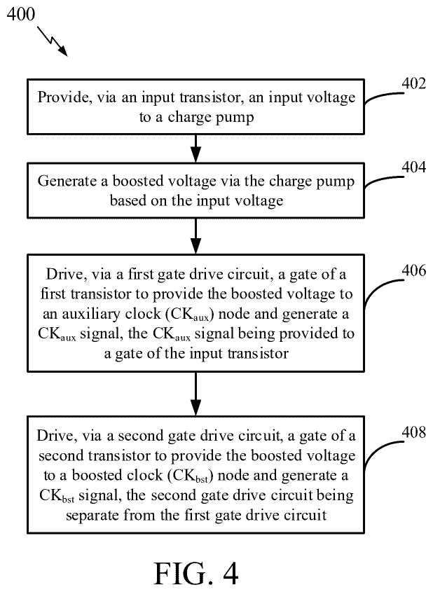

FIG. 4 is a flow diagram illustrating example operations 400 for clock generation, in accordance with certain aspects of the present disclosure. The operations 400 may be performed, for example, by a clock generation circuit such as the clock bootstrap circuit 300 of FIG. 3.

At block 402, the clock generation circuit provides, via an input transistor (e.g., transistor M1), an input voltage to a charge pump.

At block 404, the clock generation circuit generates a boosted voltage (e.g., at node n₂) via the charge pump based on the input voltage.

At block 406, the clock generation circuit drives, via a first gate drive circuit (e.g., gate drive circuit 322), a gate of a first transistor (e.g., transistor M2a) to provide the boosted voltage to an auxiliary clock (CKₐᵤₓ) node and generate a CKₐᵤₓ signal, the CKₐᵤₓ signal being provided to a gate of the input transistor.

At block 408, the clock generation circuit drives, via a second gate drive circuit (e.g., gate drive circuit 320), a gate of a second transistor to provide the boosted voltage to a boosted clock (CK_{bst}) node and generate a CK_{bst} signal, the second gate drive circuit being separate from the first gate drive circuit.

In some aspects, generating the boosted voltage may include: providing a supply voltage (e.g., VDD) to a first terminal of a capacitive element (e.g., C_{bst}) when a clock (CK) signal is logic low; coupling a reference potential node to a second terminal of the capacitive element when the CK signal is logic low; and providing the input voltage to a second terminal of the capacitive element when the CK signal is logic high. In some aspects, coupling the reference potential node to the second terminal of the capacitive element includes: turning on a first charge pump transistor (e.g., transistor M9) using a complementary CK (CK_{b}) signal; and providing the supply voltage to the first terminal of the capacitive element includes turning on a second charge pump transistor (e.g., transistor M6) using the CKₐᵤₓ signal or the CK_{bst} signal.

In some aspects, driving the gate of the first transistor includes turning on the first transistor to provide the boosted voltage to the CKₐᵤₓ node when an input CK signal is logic high. Driving the gate of the second transistor may include tuning on the second transistor to provide the boosted voltage to the CK_{bst} node when the input CK signal is logic high. In some aspects, driving the gate of the first transistor includes providing the input voltage to the gate of the first transistor to turn off the first transistor when the input CK signal is logic low. Driving the gate of the second transistor may include providing the input voltage to the gate of the second transistor to turn off the second transistor when the input CK signal is logic low. In some aspects, the clock generation circuit may pull down voltages at the CKₐᵤₓ node and the CK_{bst} node when an input CK signal is logic low.

### Example Aspects

Aspect 1: A clock generation circuit, comprising: a charge pump including a capacitive element; a first transistor coupled between a first terminal of the capacitive element and an auxiliary clock (CKₐᵤₓ) node; a second transistor coupled between the first terminal of the capacitive element and a boosted clock (CK_{bst}) node; an input transistor with a gate coupled to the CKₐᵤₓ node, a drain coupled to an input voltage node, and a source coupled to a second terminal of the capacitive element; a first gate drive circuit coupled to a gate of the first transistor; and a second gate drive circuit coupled to a gate of the second transistor, the second gate drive circuit being separate from the first gate drive circuit.

Aspect 2: The clock generation circuit of Aspect 1, wherein: the first gate drive circuit includes a third transistor with a source coupled to a voltage rail, and a fourth transistor with a source coupled to the source of the input transistor, drains of the third transistor and the fourth transistor being coupled to the gate of the first transistor; and the second gate drive circuit includes a fifth transistor with a source coupled to the voltage rail, and a sixth transistor with a source coupled to the source of the input transistor, drains of the fifth transistor and the sixth transistor being coupled to the gate of the second transistor.

Aspect 3: The clock generation circuit of Aspect 2, wherein the first gate drive circuit further includes a seventh transistor with a source coupled to the source of the input transistor and a drain coupled to the gate of the first transistor.

Aspect 4: The clock generation circuit of Aspect 2 or 3, wherein: gates of the third transistor and the fifth transistor are coupled to a clock (CK) node; and gates of the fourth transistor and the sixth transistor are coupled to the CKₐᵤₓ node.

Aspect 5: The clock generation circuit according to any of Aspects 2-4, wherein the charge pump further comprises: a first charge pump transistor with a gate coupled to a complementary clock (CK_{b}) node, a source coupled to a reference potential node, and a drain coupled to the second terminal of the capacitive element; and a second charge pump transistor with a source coupled to a voltage rail and a drain coupled to the first terminal of the capacitive element.

Aspect 6: The clock generation circuit of Aspect 5, wherein the gate of the second charge pump transistor is coupled to the CKₐᵤₓ node or the CK_{bst} node.

Aspect 7: The clock generation circuit according to any of Aspects 1-6, further comprising a pull-down circuit coupled to the CKₐᵤₓ node and the CK_{bst} node.

Aspect 8: The clock generation circuit of Aspect 7, wherein the pull-down circuit comprises a third transistor with a source coupled to a reference potential node, a drain coupled to the CKₐᵤₓ node and the CK_{bst} node, and a gate coupled to a CK_{b} node.

Aspect 9: The clock generation circuit of Aspect 8, wherein the pull-down circuit further comprises: a fourth transistor with a drain coupled to the CKₐᵤₓ node, a source coupled to the drain of the third transistor, and a gate coupled to a voltage rail; and a fifth transistor with a drain coupled to the CK_{bst} node, a source coupled to the drain of the third transistor, and a gate coupled to the voltage rail.

Aspect 10: The clock generation circuit of Aspect 9, wherein the pull-down circuit further comprises a sixth transistor with a source coupled to the voltage rail, a gate coupled to the CK_{b} node, and a drain coupled to the sources of the fourth transistor and the fifth transistor.

Aspect 11: A method for clock generation, comprising: providing, via an input transistor, an input voltage to a charge pump; generating a boosted voltage via the charge pump based on the input voltage; driving, via a first gate drive circuit, a gate of a first transistor to provide the boosted voltage to an auxiliary clock (CKₐᵤₓ) node and generate a CKₐᵤₓ signal, the CKₐᵤₓ signal being provided to a gate of the input transistor; and driving, via a second gate drive circuit, a gate of a second transistor to provide the boosted voltage to a boosted clock (CK_{bst}) node and generate a CK_{bst} signal, the second gate drive circuit being separate from the first gate drive circuit.

Aspect 12: The method of Aspect 11, wherein generating the boosted voltage comprises: providing a supply voltage to a first terminal of a capacitive element when a clock (CK) signal is logic low; coupling a reference potential node to a second terminal of the capacitive element when the CK signal is logic low; and providing the input voltage to a second terminal of the capacitive element when the CK signal is logic high.

Aspect 13: The method of Aspect 12, wherein: coupling the reference potential node to the second terminal of the capacitive element includes turning on a first charge pump transistor using a complementary CK (CK_{b}) signal; and providing the supply voltage to the first terminal of the capacitive element includes turning on a second charge pump transistor using the CKₐᵤₓ signal or the CK_{bst} signal.

Aspect 14: The method according to any of Aspects 11-13, wherein: driving the gate of the first transistor includes turning on the first transistor to provide the boosted voltage to the CKₐᵤₓ node when a clock (CK) signal is logic high; and driving the gate of the second transistor includes tuning on the second transistor to provide the boosted voltage to the CK_{bst} node when the CK signal is logic high.

Aspect 15: The method of Aspect 14, wherein: driving the gate of the first transistor includes providing the input voltage to the gate of the first transistor to turn off the first transistor when the CK signal is logic low; and driving the gate of the second transistor includes providing the input voltage to the gate of the second transistor to turn off the second transistor when the CK signal is logic low.

Aspect 16: The method according to any of Aspects 11-15, further comprising pulling down voltages at the CKₐᵤₓ node and the CK_{bst} node when a clock (CK) signal is logic low.

Aspect 17: A sample-and-hold circuit, comprising: a sampling transistor coupled to an input voltage node; and a clock generation circuit comprising: a charge pump including a capacitive element; a first transistor coupled between a first terminal of the capacitive element and an auxiliary clock (CKₐᵤₓ) node; a second transistor coupled between the first terminal of the capacitive element and a boosted clock (CK_{bst}) node, CK_{bst} node being coupled to a gate of the sampling transistor; an input transistor with a gate coupled to the CKₐᵤₓ node, a drain coupled to the input voltage node, and a source coupled to a second terminal of the capacitive element; a first gate drive circuit coupled to a gate of the first transistor; and a second gate drive circuit coupled to a gate of the second transistor, the second gate drive circuit being separate from the first gate drive circuit.

Aspect 18: The sample-and-hold circuit of Aspect 17, wherein: the first gate drive circuit includes a third transistor with a source coupled to a voltage rail, and a fourth transistor with a source coupled to the source of the input transistor, drains of the third transistor and the fourth transistor being coupled to the gate of the first transistor; and the second gate drive circuit includes a fifth transistor with a source coupled to the voltage rail, and a sixth transistor with a source coupled to the source of the input transistor, drains of the fifth transistor and the sixth transistor being coupled to the gate of the second transistor.

Aspect 19: The sample-and-hold circuit of Aspect 18, wherein the first gate drive circuit further includes a seventh transistor with a source coupled to the source of the input transistor and a drain coupled to the gate of the first transistor.

Aspect 20: The sample-and-hold circuit of Aspect 18 or 19, wherein: gates of the third transistor and the fifth transistor are coupled to a clock (CK) node; and gates of the fourth transistor and the sixth transistor are coupled to the CKₐᵤₓ node.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

What is claimed is:

1. A clock generation circuit, comprising:
a charge pump including a capacitive element;
a first transistor coupled between a first terminal of the capacitive element and an auxiliary clock (CKₐᵤₓ) node;
a second transistor coupled between the first terminal of the capacitive element and a boosted clock (CK_{bst}) node;
an input transistor with a gate coupled to the CKₐᵤₓ node, a drain coupled to an input voltage node, and a source coupled to a second terminal of the capacitive element;
a first gate drive circuit coupled to a gate of the first transistor; and
a second gate drive circuit coupled to a gate of the second transistor, the second gate drive circuit being separate from the first gate drive circuit.

2. The clock generation circuit of claim 1, wherein:
the first gate drive circuit includes a third transistor with a source coupled to a voltage rail, and a fourth transistor with a source coupled to the source of the input transistor, drains of the third transistor and the fourth transistor being coupled to the gate of the first transistor; and
the second gate drive circuit includes a fifth transistor with a source coupled to the voltage rail, and a sixth transistor with a source coupled to the source of the input transistor, drains of the fifth transistor and the sixth transistor being coupled to the gate of the second transistor.

3. The clock generation circuit of claim 2, wherein the first gate drive circuit further includes a seventh transistor with a source coupled to the source of the input transistor and a drain coupled to the gate of the first transistor.

4. The clock generation circuit of claim 2, wherein:
gates of the third transistor and the fifth transistor are coupled to a clock (CK) node; and
gates of the fourth transistor and the sixth transistor are coupled to the CKₐᵤₓ node.

5. The clock generation circuit of claim 2, wherein the charge pump further comprises:
a first charge pump transistor with a gate coupled to a complementary clock (CK_{b} node, a source coupled to a reference potential node, and a drain coupled to the second terminal of the capacitive element; and
a second charge pump transistor with a source coupled to a voltage rail and a drain coupled to the first terminal of the capacitive element.

6. The clock generation circuit of claim 5, wherein the gate of the second charge pump transistor is coupled to the CKₐᵤₓ node or the CK_{bst} node.

7. The clock generation circuit of claim 1, further comprising a pull-down circuit coupled to the CKₐᵤₓ node and the CK_{bst} node.

8. The clock generation circuit of claim 7, wherein the pull-down circuit comprises a third transistor with a source coupled to a reference potential node, a drain coupled to the CKₐᵤₓ node and the CK_{bst} node, and a gate coupled to a CK_{b} node.

9. The clock generation circuit of claim 8, wherein the pull-down circuit further comprises:
a fourth transistor with a drain coupled to the CKₐᵤₓ node, a source coupled to the drain of the third transistor, and a gate coupled to a voltage rail; and
a fifth transistor with a drain coupled to the CK_{bst} node, a source coupled to the drain of the third transistor, and a gate coupled to the voltage rail.

10. The clock generation circuit of claim 9, wherein the pull-down circuit further comprises a sixth transistor with a source coupled to the voltage rail, a gate coupled to the CK_{b} node, and a drain coupled to the sources of the fourth transistor and the fifth transistor.

11. A method for clock generation, comprising:
providing, via an input transistor, an input voltage to a charge pump;
generating a boosted voltage via the charge pump based on the input voltage;
driving, via a first gate drive circuit, a gate of a first transistor to provide the boosted voltage to an auxiliary clock (CKₐᵤₓ) node and generate a CKₐᵤₓ signal, the CKₐᵤₓ signal being provided to a gate of the input transistor; and
driving, via a second gate drive circuit, a gate of a second transistor to provide the boosted voltage to a boosted clock (CK_{bst}) node and generate a CK_{bst} signal, the second gate drive circuit being separate from the first gate drive circuit.

12. The method of claim 11, wherein generating the boosted voltage comprises:
providing a supply voltage to a first terminal of a capacitive element when a clock (CK) signal is logic low;
coupling a reference potential node to a second terminal of the capacitive element when the CK signal is logic low; and
providing the input voltage to a second terminal of the capacitive element when the CK signal is logic high.

13. The method of claim 12, wherein:
coupling the reference potential node to the second terminal of the capacitive element includes turning on a first charge pump transistor using a complementary CK (CK_{b}) signal; and
providing the supply voltage to the first terminal of the capacitive element includes turning on a second charge pump transistor using the CKₐᵤₓ signal or the CK_{bst} signal.

14. The method of claim 11, wherein:
driving the gate of the first transistor includes turning on the first transistor to provide the boosted voltage to the CKₐᵤₓ node when a clock (CK) signal is logic high; and
driving the gate of the second transistor includes tuning on the second transistor to provide the boosted voltage to the CK_{bst} node when the CK signal is logic high.

15. The method of claim 14, wherein:
driving the gate of the first transistor includes providing the input voltage to the gate of the first transistor to turn off the first transistor when the CK signal is logic low; and
driving the gate of the second transistor includes providing the input voltage to the gate of the second transistor to turn off the second transistor when the CK signal is logic low.

16. The method of claim 11, further comprising pulling down voltages at the CKₐᵤₓ node and the CK_{bst} node when a clock (CK) signal is logic low.

17. A sample-and-hold circuit, comprising:
a sampling transistor coupled to an input voltage node; and
a clock generation circuit comprising:
a charge pump including a capacitive element;
a first transistor coupled between a first terminal of the capacitive element and an auxiliary clock (CKₐᵤₓ) node;
a second transistor coupled between the first terminal of the capacitive element and a boosted clock (CK_{bst}) node, CK_{bst} node being coupled to a gate of the sampling transistor;
an input transistor with a gate coupled to the CKₐᵤₓ node, a drain coupled to the input voltage node, and a source coupled to a second terminal of the capacitive element;
a first gate drive circuit coupled to a gate of the first transistor; and
a second gate drive circuit coupled to a gate of the second transistor, the second gate drive circuit being separate from the first gate drive circuit.

18. The sample-and-hold circuit of claim 17, wherein:
the first gate drive circuit includes a third transistor with a source coupled to a voltage rail, and a fourth transistor with a source coupled to the source of the input transistor, drains of the third transistor and the fourth transistor being coupled to the gate of the first transistor; and
the second gate drive circuit includes a fifth transistor with a source coupled to the voltage rail, and a sixth transistor with a source coupled to the source of the input transistor, drains of the fifth transistor and the sixth transistor being coupled to the gate of the second transistor.

19. The sample-and-hold circuit of claim 18, wherein the first gate drive circuit further includes a seventh transistor with a source coupled to the source of the input transistor and a drain coupled to the gate of the first transistor.

20. The sample-and-hold circuit of claim 18, wherein:
gates of the third transistor and the fifth transistor are coupled to a clock (CK) node; and
gates of the fourth transistor and the sixth transistor are coupled to the CKₐᵤₓ node.
